(19) United States
(12) Patent Application Publication
(10) Pub. No.: US 2008/0068802 A1
(43) Pub. Date: Mar. 20, 2008

(54) Heatsink device with vapor chamber

(75) Inventors: Win-Haw Chen, Taipei (TW); Mao-Ching Lin, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/523,075

(22) Filed: Sep. 19, 2006

(51) Int. Cl. H05K 7/20

(52) U.S. Cl. 361/703

(57) ABSTRACT

A heatsink device with vapor chamber is provided. The heatsink device with vapor chamber has a lid, a heat dissipation base attached to the heat generating component, and a heat conductive powder. The lid is bonded to the heat dissipation base to form an inclosed accommodation space therebetween for accommodating a heat dissipation liquid that dissipate heat according to the principle of liquid-gas phase change. A bump is disposed on the inner surface of the heat dissipation base toward the accommodation space and opposite to the heat generating component. In addition, the heat conductive powder is distributed on the above inner surface for forming capillary spaces. Meanwhile, as the conductive powder deposited on the rim of the bump is more than that on other areas, more capillary spaces are provided to conduct heat more effectively via the capillary phenomenon, thereby improving the heat dissipation effect.

### BACKGROUND OF THE INVENTION

1. Field of Invention

The present invention relates to a heatsink device with vapor chamber, and more particularly, to a heatsink device with vapor chamber, which increases the capillary spaces around the heat source in the chamber to effectively improve the heat dissipation effect via the capillary phenomenon.

2. Related Art

Please refer to FIG. 1 of a schematic structural view of a conventional heatsink device with vapor chamber. As shown in FIG. 1, a prior heatsink device with vapor chamber has a chamber 112 for accommodating a heat dissipation liquid 114 that dissipates heat via liquid-gas phase change. The inner side of the chamber 112 opposite to a heat generating component 120 is usually a plane with a heat conductive powder 113 uniformly distributed and sintered thereon. The sintered heat conductive powder 113 may form a plurality of capillary spaces for accommodating the heat dissipation liquid 114, i.e., the heat dissipation liquid 114 infiltrates into the heat conductive powder 113. The heatsink device further has a heat dissipation base 111 disposed on the section facing the heat generating component 120. When the heatsink device intends to dissipate the heat generated by the heat generating component 120, the heat dissipation base 111 contacts the heat generating component 120 so as to conduct the heat into the heat dissipation liquid 114. The heat conductive powder 113 is used to assist the heat dissipation base 111 to conduct heat and dissipate the heat uniformly to accelerate heat conduction into the heat dissipation liquid 114. A plurality of fins 115 is disposed on the surface of the chamber 112 to facilitate dissipating heat.

As soon as the heat dissipation liquid 114 absorbs heat, the temperature thereof rises gradually. Particularly, the heat dissipation liquid 114 infiltrating into the heat conductive powder 113 is closest to the heat generating component 120, and thus the temperature thereof rises most rapidly. When the temperature reaches the boiling point, the heat dissipation liquid 114 changes from liquid to gas, and the original position thereof is taken by other liquid heat dissipation liquid 114. At this time, the compensation speed of the heat dissipation liquid 114 is accelerated due to the capillary phenomenon caused by the capillary spaces, so as to continuously perform the cycle of liquid-gas phase change to dissipate the heat generated by the heat generating component 120.

However, the prior art has the following inevitable disadvantages, i.e., the thickness of the heat conductive powder may easily affect the heat dissipation effect of the heat dissipation liquid.

1. If the distributed heat conductive powder is too thin, the formed capillary spaces are too few to accommodate sufficient heat dissipation liquid. As such, when the heat dissipation liquid absorbs heat to change into gas, other liquid heat dissipation liquids cannot take the vacancies in the capillary spaces rapidly via the capillary phenomenon, which may hinder the heat conduction and thus the heat cannot be dissipated quickly.

2. If the distributed heat conductive powder is too thick, the sintered heat conductive powder becomes too dense such that the heat dissipation liquid cannot infiltrate into the capillary spaces at the bottom of the heat conductive powder. As such, the heat cannot be conducted into the heat dissipation liquid, which may result in the failure of the heat dissipation with the heat dissipation liquid.

### SUMMARY OF THE INVENTION

In view of the above disadvantages, the objective of the present invention is to provide a heatsink device with vapor chamber, which increases capillary spaces at the periphery of a portion in the chamber opposite to the heat generating component, such that the heat dissipation liquid can effectively utilize the capillary phenomenon to rapidly compensate the gaseous heat dissipation liquid, and accelerate the cycle of liquid-gas phase change of the heat dissipation liquid, thereby quickly dissipating the heat generated by the heat generating component to enhance the heat dissipation effect.

In order to achieve the above objective, the present invention provides a heatsink device with vapor chamber, which is attached to a heat generating component and utilizes the principle of liquid-gas phase change to dissipate the heat generated by the heat generating component. The heatsink device with vapor chamber comprises a lid, a heat dissipation base and a heat conductive powder. The heat dissipation base is bonded to the lid to form an inclosed accommodation space therebetween for accommodating the heat dissipation liquid that dissipates heat according to the principle of liquid-gas phase change. The heat dissipation base has a base attachment surface attached to the heat generating component and an inner surface facing the accommodation space, so as to conduct the heat generated by the heat generating component into the heat dissipation liquid through the base attachment surface and the inner surface.

A bump is disposed on the inner surface of the heat dissipation base opposite to the base attachment surface, and is used to increase the heat conductive path, so as to uniformly dissipate the heat and accelerate the heat conduction into the heat dissipation liquid.

On the inner surface of the heat dissipation base, the heat conductive powder is uniformly distributed to form a plurality of capillary spaces to accommodate the heat dissipation liquid. In other words, the heat dissipation liquid infiltrates into the heat conductive powder via the capillary phenomenon of the capillary spaces. More heat conductive powder is deposited on the rim of the bump when being distributed, so as to form more capillary spaces than that on other areas. As such, more heat dissipation liquid can be accommodated to achieve the accommodation effect like a reservoir.

When the heat dissipation base is attached to the heat generating component, the heat generated by the heat generating component is conducted to the heat dissipation liquid via the base. Moreover, the heat conductive powder may assist the heat dissipation base to conduct heat, wherein the heat is dissipated uniformly to accelerate the heat dissipation into the heat dissipation liquid. The temperature of the heat dissipation liquid gradually rises on absorbing heat. More particularly, the temperature of the heat dissipation liquid infiltrating into the heat conductive powder and being closest to the heat generating component rises most rapidly. When the temperature reaches the boiling point, the heat dissipation liquid change into gas, and the position thereof is taken by other liquid heat dissipation liquid. In addition, the compensation speed of the heat dissipation liquid is accelerated via the capillary phenomenon, so as to continuously perform the cycle of liquid-gas phase change to dissipate the heat generated by the heat generating component. As the rim of the bump has most capillary spaces disposed thereon, and the amount of the heat dissipation liquid accommodated therein is the largest, the capillary phenomenon is most vigorous here. Therefore, besides that the gaseous heat dissipation liquid can be rapidly replaced by the liquid heat dissipation liquid, the rim of the bump can also achieve a satisfactory heat dissipation effect.

Moreover, the heat dissipation base is generally formed by at least one selected from the group of materials of good heat conductive capability consisting of Cu, Al, graphite, SiC, AlN and BN. The heat conductive powder is formed by at least one selected form the group consisting Cu, Fe or Al powder.

Further, on practical demands, the heatsink device with vapor chamber may have different designs. For example, (1) fins are added on the lid to enlarge the heat conductive area to facilitate dissipating heat; (2) the bump is formed by directly extending toward the accommodation space from the inner surface of the heat dissipation base; (3) as the heat generating component may have a plurality of portions that can generate heat (referred to as heat generating portions below), the area of the bump is designed to be larger or smaller than that of the base attachment surface, so as to be corresponding to the quantity and position of the heat generating portions; (4) the base attachment surface is recessed into the heat dissipation base facing the accommodation space, and the shape of the recessed position enables the heat dissipation base to be tightly attached to the heat generating component, so as to achieve the optimal heat dissipation effect. Moreover, the bump can be formed opposite to the recessed position of the base attachment surface and thus opposite to the heat dissipation portions. Further, as the rim of the bump has a large quantity of capillary spaces disposed thereon, the heat dissipation liquid can rapidly dissipate heat via the capillary phenomenon, thus enhancing the heat dissipation effect.

In comparison with the prior art, the heatsink device with vapor chamber disclosed in the present invention has the following advantages and remarkable efficacies.

1. As mentioned above, a thicker layer of heat conductive powder is deposited on the rim of the bump, so more capillary spaces are formed for accommodating a larger amount of heat dissipation liquid, thus achieving an accommodation effect like a reservoir. Moreover, besides that the thicker heat conductive powder can facilitate the heat dissipation, when the capillary spaces of the surrounding heat conductive powder cannot be filled in time as the heat dissipation liquid becomes gas, the heat dissipation liquid accommodated in the thick heat conductive powder may rapidly take the vacancies in the capillary spaces via the capillary phenomenon, so as to avoid poor heat dissipation effect due to insufficient heat dissipation liquid in the vacancies, and improve the liquid-gas cycle of the heat dissipation liquid.

2. Though a thicker layer of heat conductive powder is deposited on the rim of the bump, the heat conductive powder may not be too dense to prevent the heat dissipation liquid infiltrating into the capillary spaces at the bottom, thus the heat dissipation effect will not be affected.

To acquire further understandings to the objective, implementing method and functions of the present invention, they are illustrated in detail below with reference to the drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a schematic structural view of the conventional art;

FIG. 2A is a schematic structural view of the heatsink device according to a first embodiment of the present invention;

FIG. 2B is a detailed view of a portion of the elements according to the first embodiment of the present invention;

FIG. 3 is a schematic view of the heat conduction according to the present invention;

FIG. 4 is a schematic view of the heat conduction of the capillary spaces according to the present invention;

FIG. 5 is a schematic structural view of the heatsink device according to a second embodiment of the present invention;

FIG. 6 is a schematic structural view of the heatsink device according to a third embodiment of the present invention; and

FIG. 7 is a schematic structural view of the heatsink device according to a fourth embodiment of the present invention.

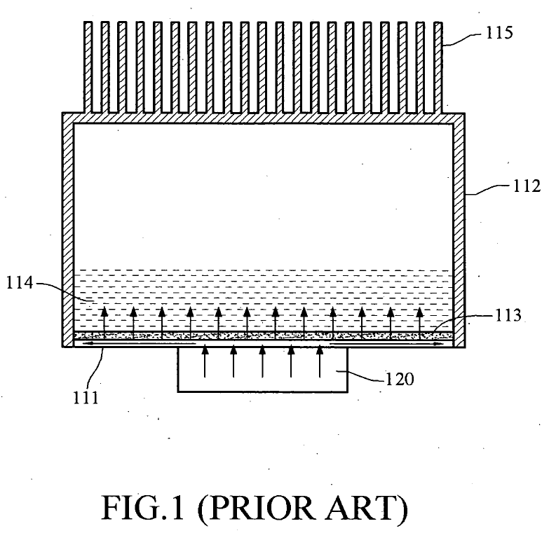

### DETAILED DESCRIPTION OF THE INVENTION

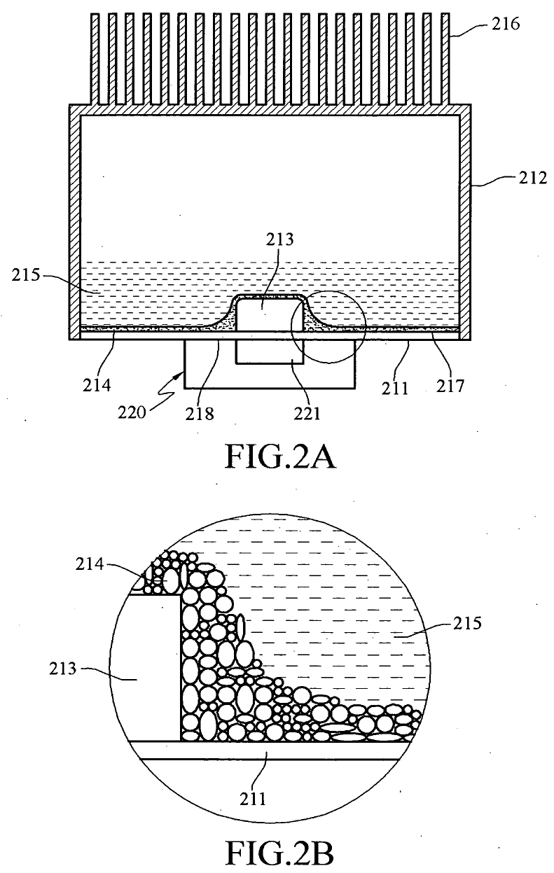

Please refer to FIGS. 2A and 2B of a schematic structural view and a detailed view of a portion of the elements in the heatsink device according to the first embodiment of the present invention. As shown in FIGS. 2A and 2B, the heatsink device includes a heat dissipation base 211, a lid 212, a bump 213, a heat conductive powder 214, a heat dissipation liquid 215 and a plurality of fins 216. A heat generating component 220 with a heat generating portion 221 that can generate heat is disposed externally.

The heat dissipation base 211 has a base attachment surface 218 for being attached to the heat generating component 220 and an inner surface 217 facing the accommodation space. The bump 213 is disposed on the inner surface 217 opposite to the base attachment surface 218. In addition, when the heat dissipation base 211 is bonded to the lid 212, an inclosed accommodation space is formed therebetween for accommodating the heat dissipation liquid 215. The heat conductive powder 214 is distributed on the inner surface 217, so as to form a plurality of capillary spaces to accommodating the heat dissipation liquid 215. A larger amount of heat conductive powder 214 is deposited on the rim of the bump 213 to form more capillary spaces to enhance the heat dissipation effect.

The bump 213 is mainly disposed opposite to the heat generating portion 221 of the heat generating component 220 when the heat dissipation base is attached to the heat generating component 220, so as to increase the heat conductive path to dissipate the heat uniformly when the base attachment surface 218 absorbs the heat generated by the heat generating portion 221, and conduct the heat into the heat dissipation liquid 215 via the inner surface 217 together with the heat conductive powder 214. The fins 216 are disposed on the external surface of the lid 212, so as to enlarge the heat distribution area to enhance the heat dissipation effect.

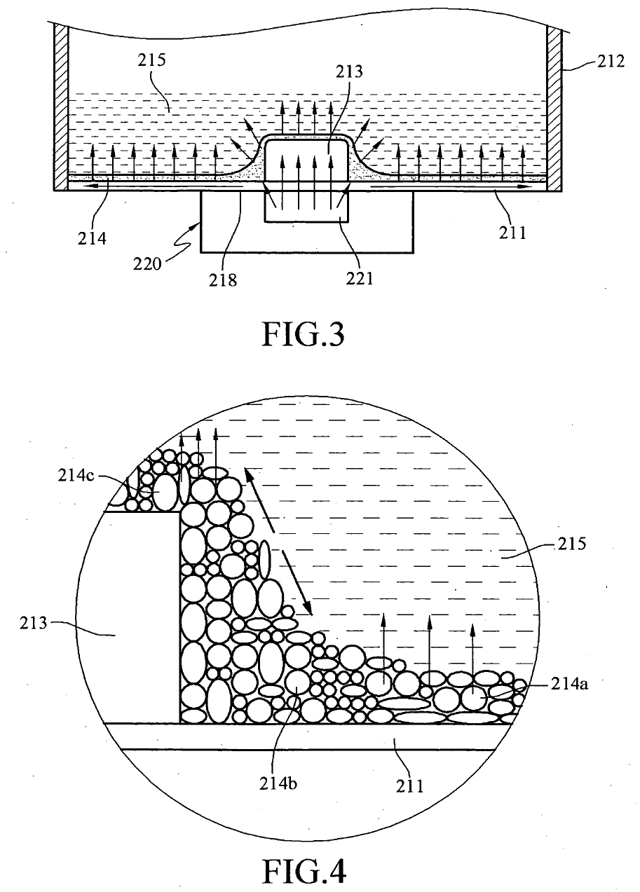

Please refer to FIG. 3 of a schematic view of the heat conduction according to the present invention. As shown in FIG. 3, when the heat dissipation base 211 is attached to the heat generating component 220, the heat can be conducted into the heat dissipation liquid 215. The heat conductive powder 214 can assist the heat dissipation base 211 to dissipate the heat uniformly, so as to facilitate dissipating heat into the heat dissipation liquid 215. The bump 213 is opposite to the heat generating portion 221 of the heat generating component 220, so as to extend the heat conductive path to dissipate the heat uniformly. In addition, as the heat conductive powder 214 on the rim of the bump 213 is thicker and has more capillary spaces, a larger amount of heat dissipation liquid 215 is accommodated therein to enhance the heat dissipation effect.

Please refer to FIG. 4 of a schematic view of the heat conduction of the capillary spaces according to the present invention. As shown in FIG. 4, when the heat dissipation liquid 215 accommodated in the capillary spaces of the heat conductive powder (214a or 214c) on the surface of the bump 213 or heat dissipation base 211 changes into gas by absorbing heat to reach the boiling point, and the heat dissipation liquid 215 from other areas cannot complement the vacancies in time, the heat dissipation liquid 215 contained in the thicker heat conductive powder 214b between the bump 213 and the heat dissipation base 211 can be quickly adopted to complement the capillary spaces of the heat conductive powder 214a or heat conductive powder 214c via the capillary phenomenon.

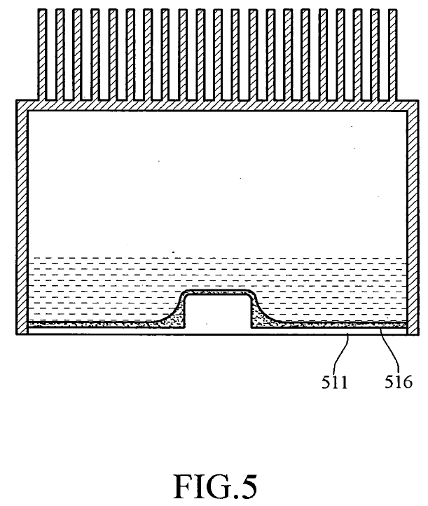

Please refer to FIG. 5 of a schematic structural view of the heatsink device according to the second embodiment of the present invention. As shown in FIG. 5, the bump 213 can be integrally formed with the heat dissipation base 511. The heat dissipation base 511 is directly extended toward the accommodation space from the inner surface 516 to form the bump 213.

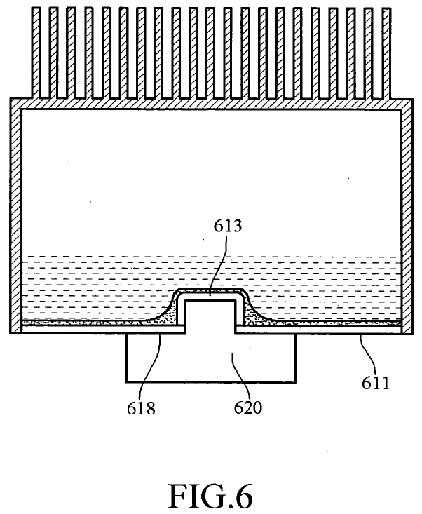

Please refer to FIG. 6 of a schematic structural view of the heatsink device according to the third embodiment of the present invention. As shown in FIG. 6, the base attachment surface 618 of a heat dissipation base 611 is recessed into a heat dissipation base 611 toward the accommodation space. Such design is meant to make the heat dissipation base 611 be completely attached to a heat generating component 620, so as to achieve the optimal heat dissipation effect. Moreover, a bump 613 can be designed into a raised shape opposite to the recessed position of the base attachment surface 618, so as to enhance the heat dissipation effect.

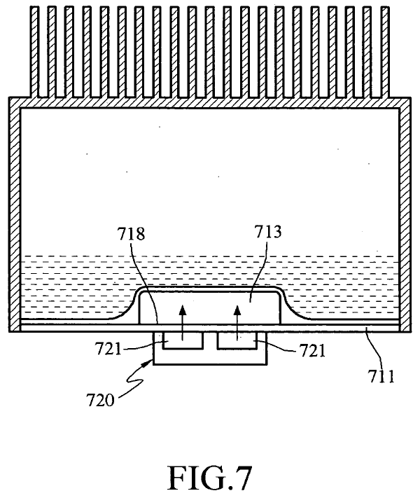

Please refer to FIG. 7 of a schematic structural view of the heatsink device according to the fourth embodiment of the present invention. As shown in FIG. 7, the heat generating component 720 does not necessarily have only one heat generating portion 721, and to effectively dissipate the heat generated by the heat generating component 720, a bump 713 disposed on a heat dissipation base 711 can have an area larger than that of the base attachment surface 718, so as to correspondingly cover all of the heat generating portions 721, thus achieving a preferable heat dissipation effect.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heatsink device with vapor chamber, comprising:
a lid;
a heat dissipation base, bonded to the lid to form an inclosed accommodation space therebetween for accommodating a heat dissipation liquid that dissipates heat via liquid-gas phase change, having a base attachment surface attached to a heat generating component and an inner surface facing the accommodation space, wherein the base attachment surface conducts the heat through the heat dissipation base and the inner surface to the heat dissipation liquid, and the inner surface has a bump opposite to the base attachment surface; and
a heat conductive powder, distributed on the inner surface, wherein the amount of the heat conductive powder deposited on the rim of the bump is larger than that on other areas, such that the capillary spaces formed by the heat conductive powder on the rim of the bump are more than those formed on other areas.

2. The heatsink device with vapor chamber as claimed in claim 1, wherein the bump is formed by extending the inner surface toward the accommodation space.

3. The heatsink device with vapor chamber as claimed in claim 1, wherein the bump is integrally formed with the heat dissipation base.

4. The heatsink device with vapor chamber as claimed in claim 1, wherein the area of the bump is larger than that of the base attachment surface.

5. The heatsink device with vapor chamber as claimed in claim 1, wherein the area of the bump is smaller than that of the base attachment surface, and the position of the bump is opposite to the heat generating position of the heat generating component.

6. The heatsink device with vapor chamber as claimed in claim 1, wherein the base attachment surface is recessed into the heat dissipation base toward the accommodation space.

7. The heatsink device with vapor chamber as claimed in claim 5, wherein the bump is formed opposite to the recessed position in the base attachment surface.
